(19) United States
(12) Patent Application Publication
(10) Pub. No.: US 2025/0335647 A1
(43) Pub. Date: Oct. 30, 2025

(54) SYSTEMATIC TOLERANCE ASCERTAINMENT FOR SAMPLES OF A SERIES PRODUCT

(71) Applicant: Robert Bosch GmbH, Stuttgart (DE)

(72) Inventors: Philip Lucas Neureuther, Neckarwestheim (DE); Stefan Gruener, Auenwald (DE); Kim Peter Wabersich, Schwaebisch Gmuend (DE); Mark Philipp Riek, Abtsgmuend (DE)

(21) Appl. No.: 19/184,683

(22) Filed: Apr. 21, 2025

(30) Foreign Application Priority Data
Apr. 29, 2024 (DE) 10 2024 204 004.5

(51) Int. Cl. G06F 30/15

(52) U.S. Cl. CPC G06F 30/15

(57) ABSTRACT

A computer-implemented method for ascertaining a tolerance zone in an operational design domain (ODD) around a target parameter sample of a parameterizable simulation model for a product, in particular a steer-by-wire steering system and/or a steering system for highly automated driving. The method includes: determining the tolerance zone in the ODD around the target parameter sample on the basis of a maximum tolerable distance and a dissimilarity metric, wherein the dissimilarity metric defines a distance between a parameterized simulation model assigned to the target parameter sample and a parameterized simulation model.

### BACKGROUND INFORMATION

Series products (in particular large-scale series products), such as steering systems, are subject to a variation in product parameters, such as friction, elasticity, and/or inertia, due to manufacturing tolerances and manufacturing inaccuracies. Furthermore, series products are subject to additional parameter variation due to aging, e.g., due to wear and/or environmental influences. All value ranges and value combinations of the parameter variation of a series product that occur in reality form its so-called operational design domain (ODD).

In every simulation model of a (series) product, deviations occur between modeled and real behavior due to the parameter variation in the entire ODD and through simplifications in modeling. Such a simulation model including the model deviations and/or model uncertainties in the entire ODD is the basis for simulation-based product release. The necessary characterization of the model uncertainties is typically carried out today on the basis of a few selected product prototypes since complete characterization generally involves too much outlay. Below, the target version (also: ideal version) of a prototype is referred to as a product sample and its physical realization as a product specimen. The selection of the product samples for uncertainty characterization is usually based on expert opinion.

However, exact realization of the selected (ideal) product samples is not possible in practice due to finite manufacturing accuracies, which means that the product samples and the associated product specimens exhibit slightly different system behavior. Typically, the acceptable parameter tolerances for the realization of a product sample are defined by expert knowledge. Alternatively, the aim can be to manufacture and/or rework the product specimens as accurately as possible. However, this does not make it possible to rule out that parameter tolerances that are too lax are determined and/or produced, which may lead to significant system behavior deviations between product samples and product specimens. On the other hand, it also cannot be ruled out that parameter tolerances that are too strict are determined and/or produced, which can result in the system behavior of product samples and product specimens being practically identical but can incur unnecessarily high production costs.

An object of the present invention includes, for example, providing a method which ascertains how much product specimens may deviate from a specified product sample in order still to realize this product sample sufficiently with respect to its system behavior.

In comparison with traditional steering systems, steer-by-wire (SbW) steering systems and/or steering systems for highly automated driving (HAD) are subject to stricter normative requirements for product release. In order to ensure that the real testing and validation outlay does not increase extraordinarily due to the stricter release requirements for SbW and HAD steering systems of (large-scale) series productions in comparison with traditional steering systems, the industry focuses on simulation-based release processes. For such a simulation-based release, a validated and verified simulation model of the steering system with known model uncertainties is essential.

As part of the company's internal and simulation-based release process for SbW and/or HAD steering systems, the model uncertainties are to be characterized on the basis of a few selected product specimens.

A preliminary object to be achieved may therefore be to systematically select the associated product samples by means of a model-based criterion so that they represent the entire ODD of the (large-scale) series steering system with a quantifiable residual uncertainty.

Currently, there is no systematic method to ascertain meaningful parameter tolerances for the realization of the product samples so that a negligible quantitative system behavior dissimilarity between product samples and product specimens can be ensured and excessively strict or lax tolerances can thereby be avoided.

Systems theory includes various metrics that quantify the dissimilarity of two systems (systems and products can be equated below) and thus compare them. The gap metric, v-gap metric, and L2 metric are explained below.

The gap metric quantifies the dissimilarity of the uncontrolled (open-loop) input/output behavior of two systems P1 and P2 with regard to their stability and performance properties in controlled operation (closed-loop) with a scalar in the real interval [0, 1]. A metric result close to 0 means that both systems are very similar and each P1-stabilizing controller also stabilizes the system P2 with a similar controlled performance. A metric result of 0 means that the considered systems P1 and P2 behave exactly identically. On the other hand, a metric result close to or at 1 indicates that systems P1 and P2 are very dissimilar. Furthermore, the gap metric allows statements to be made about the robust stability of closed control loops with model uncertainties. An explicit controller design is necessary for evaluating the gap metric. Details on the definition and properties of the gap metric are described in chapter 17 of the book “Essentials of Robust Control,” Kemin Zhou and John C. Doyle, 1st edition, Pearson, 1997, ISBN: 9780135258332.

The systems-theoretical statements and implications of the v-gap metric are very similar to the gap metric, but the two metrics are defined fundamentally differently. For evaluating the v-gap metric, no controller design is necessary, but a winding number analysis of the systems P1 and P2 to be compared is necessary. Details on the definition and properties of the v-gap metric are described in chapter 17 of the book “Essentials of Robust Control,” Kemin Zhou and John C. Doyle, 1st edition, Pearson, 1997, ISBN: 9780135258332 or in the paper “Frequency domain uncertainty and the graph topology,” Glenn Vinnicombe, IEEE Transactions on Automatic Control, vol. 38, no. 9, pp. 1371-1383 September 1993, DOI: 10.1109/9.237648.

The definition of the L2 metric corresponds to the v-gap metric without winding number analysis. For this reason, the principal statements and implications of the two metrics are similar, but the L2 metric has less theoretical significance. Details on the definition and properties of the L2 metric are described in chapter 17 of the book “Essentials of Robust Control,” Kemin Zhou and John C. Doyle, 1st edition, Pearson, 1997, ISBN: 9780135258332.

All three dissimilarity metrics presented are known to have the following properties:
The metrics quantify the dissimilarity of two systems with regard to stability and performance properties in controlled operation on the basis of the uncontrolled input/output behavior.
The metric results can be used to decide whether two systems P1 and P2 are sufficiently similar that P1 can be considered representative of P2.
The metric results can also be interpreted as (systems-theoretical) distances between the compared systems.
For all systems to be compared, the following applies: L2 result≤v-gap result≤gap result.

### SUMMARY

A first general aspect of the present invention relates to a computer-implemented method for ascertaining a tolerance zone in an operational design domain (ODD) around a target parameter sample of a parameterizable simulation model for a product. The product may, for example, be a steer-by-wire steering system and/or a steering system for highly automated driving.

According to an example embodiment of the present invention, the method comprises determining the tolerance zone in the ODD around the target parameter sample on the basis of a maximum tolerable distance and a dissimilarity metric, wherein the dissimilarity metric defines a distance between a parameterized simulation model assigned to the target parameter sample and a parameterized simulation model.

A second general aspect of the present invention relates to a computer system designed to execute the computer-implemented method of the present invention for ascertaining a tolerance zone in an operational design domain (ODD) around a target parameter sample of a parameterizable simulation model for a product according to the first general aspect (or an embodiment thereof).

A third general aspect of the present invention relates to a computer program designed to execute the computer-implemented method of the present invention for ascertaining a tolerance zone in an operational design domain (ODD) around a target parameter sample of a parameterizable simulation model for a product according to the first general aspect (or an embodiment thereof).

A fourth general aspect of the present disclosure relates to a computer-readable medium or signal that stores and/or contains the computer program according to the third general aspect (or an embodiment thereof) of the present invention.

By means of the method disclosed herein according to the first general aspect (or an embodiment thereof) of the present invention, tolerance zones can be systematically ascertained individually for the realization (i.e., physical production) of product samples on the basis of a model-based criterion, so that the system behaviors of product samples and product specimens in each case match up to a tolerable quantitative dissimilarity. In particular, parameter tolerances for the product samples can be ascertained. The product sample to be produced is assigned to the target parameter sample, i.e., the target version (also: ideal version) of a prototype. In the realization of the product sample, a product specimen can now be built as a prototype in such a way that its parameter sample is in the tolerance zone around the target parameter sample.

In particular, in comparison with the related art, the following advantages can be achieved by the method proposed here according to the first general aspect (or an embodiment thereof):
Systematic procedure for ascertaining individual parameter tolerances (i.e., permissible value range of one or more parameters) for the realization of the product samples;
Calculable individual tolerance zones of the product parameters (i.e., permissible zone for all parameters) for all product samples;
Quantifiable system behavior dissimilarities between product samples and product specimens due to non-matching parameters in the entire ODD;
Possibility of searching for local product parameters or product combinations near a product sample that have a particularly strong influence on the system behavior thereof.

According to an example embodiment of the present invention, the method proposed here according to the first general aspect (or an embodiment thereof) can be used in the design phase and/or in system development (i.e., after the design phase) in the development of real (i.e., physical) products, e.g., steer-by-wire (SbW) steering systems.

In the design phase or in system development, for example, the present invention can be used to ascertain individual tolerance zones of the (product) parameters for the realization of all product samples (e.g., for the characterization of model uncertainties) while maintaining a tolerable system behavior dissimilarity between product samples and product specimens. In particular, individual parameter tolerances can be calculated for all product samples to be realized, in which the tolerable system behavior dissimilarity is maintained in each case. This is important since prototypes of which the parameters exactly match the target parameter samples can be produced and/or retrofitted (e.g., shimming) with difficulty or only with considerable effort.

In addition, in the design phase, for example, intermediate results of the method according to the first general aspect (or an embodiment thereof) of the present invention as well as additional mathematical analyses can be used to find local product parameters and/or their combinations near a product sample that have a particularly strong influence on the system behavior thereof.

The target parameter sample may be one of a plurality of representative parameter samples in the ODD, i.e., of a plurality of parameter samples that represent the entire ODD of the (series) product with a quantifiable residual uncertainty. The realized product sample (more precisely: the product specimen) is then a representative product specimen. On the other hand, the target parameter sample does not have to be a representative parameter sample, i.e., it may be specified arbitrarily or for other reasons (e.g., as a boundary sample) as a target for the realization.

On the basis of the representative product specimens, the uncertainties caused by parameter variation and simplifications in modeling between the real product behavior and its modeled behavior can be systematically characterized in the entire ODD in the further system development. The representative product specimens including the characterized model uncertainties can subsequently be used for the development of a product control and/or for product release.

The example method according provided here according to the first general aspect (or an embodiment thereof) of the present invention can be used in particular as part of a process for the release of SbW and HAD steering systems. The realization of product samples representative of the entire ODD can be used in the validation and/or verification of the steering systems.

The example method provided here according to the first general aspect (or an embodiment thereof) of the present invention can be performed analytically in whole or in part. This avoids sampling a plurality of parameter samples around the target parameter sample. In embodiments, the tolerance zone can sometimes be determined exactly.

### BRIEF DESCRIPTION OF THE DRAWINGS

FIG. 1 schematically illustrates exemplary embodiments of a computer-implemented method of the present invention for ascertaining a tolerance zone in an operational design domain

(ODD) around a target parameter sample of a parameterizable simulation model for a product, in particular a steer-by-wire steering system and/or a steering system for highly automated driving.

FIG. 2 illustrates an exemplary embodiment of the method.

FIG. 3A illustrates the exemplary ODD of FIG. 3B with an exemplary and arbitrary plurality of parameterized simulation models.

FIG. 3B illustrates an exemplary ODD with a target parameter sample surrounded by a tolerance zone.

### DETAILED DESCRIPTION OF EXAMPLE EMBODIMENTS

The method 100 proposed in this disclosure is aimed at ascertaining a tolerance zone 30 in an operational design domain (ODD) around a target parameter sample 10 of a parameterizable simulation model for a product, in particular a steer-by-wire steering system and/or a steering system for highly automated driving. Alternatively or additionally, the method 100 may also be aimed at producing a product sample in the form of a product specimen that realizes the product sample.

The method 100 is wholly or partially analytical and requires that the parameterizable simulation model is in analytical form.

First, a computer-implemented method 100 for ascertaining a tolerance zone 30 in an operational design domain (ODD) around a target parameter sample 10 of a parameterizable simulation model for a product is disclosed. In particular, the product may be a series product, i.e., may be produced in series. Although the method 100 can also be used for a non-series product or a small series, it is particularly useful when a plurality of similar products, which may nevertheless be different (e.g., for production-related and/or material-related reasons), are to be produced. The plurality of similar products may, for example, comprise >1e5 products per year, >5e5 products per year, or >1e6 products per year.

The product may, for example, be a steer-by-wire steering system. Alternatively or additionally, the product may be a steering system for automated, in particular highly automated, driving.

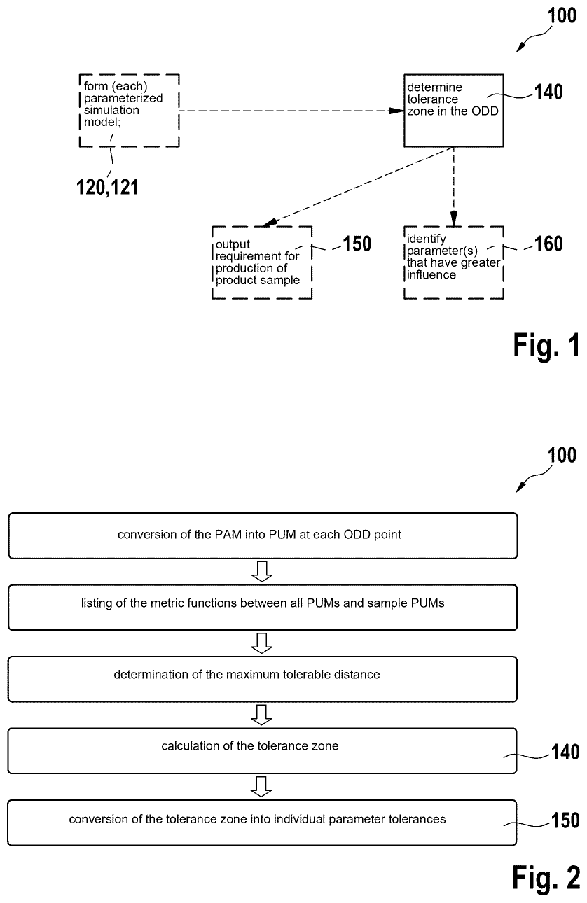

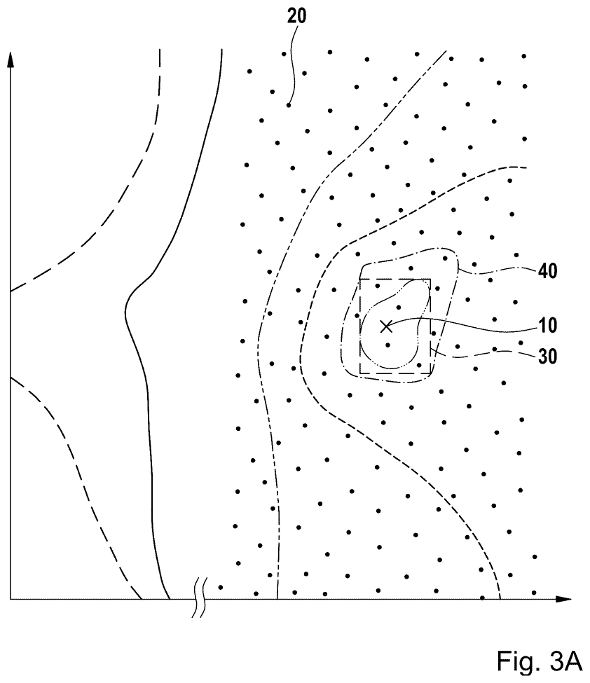

As schematically illustrated in FIG. 1, for example, the method 100 comprises determining 140 the tolerance zone 30 in the ODD around the target parameter sample 10 on the basis of a maximum tolerable distance and a dissimilarity metric, wherein the dissimilarity metric defines a distance between a parameterized simulation model assigned to the target parameter sample 10 (always the same for the parameterized simulation models, referred to as sample PUM in FIG. 2) and a parameterized simulation model.

The dissimilarity metric can be based on a gap metric, a v-gap metric, and/or an L2 metric. In particular, the dissimilarity metric can be the gap metric, the v-gap metric, or the 2 metric. Alternatively, the dissimilarity metric can be based on a combination of the gap metric, the v-gap metric, and/or the L2 metric. The dissimilarity metric can output a quantitative measure of the dissimilarity of a pair of parameterized simulation models, i.e., a quantitative measure of how similar or dissimilar the two parameterized simulation models of the pair are. In this respect, the dissimilarity metric could also be referred to as a similarity metric or comparison metric. The quantitative measure output by the dissimilarity metric can be referred to as a distance. If the two parameterized simulation models of a pair are similar, the distance can be small. In particular, if the two parameterized simulation models of a pair are identical (i.e., maximally similar), the distance can be zero. However, if the two parameterized simulation models of a pair are not similar, the distance can be high.

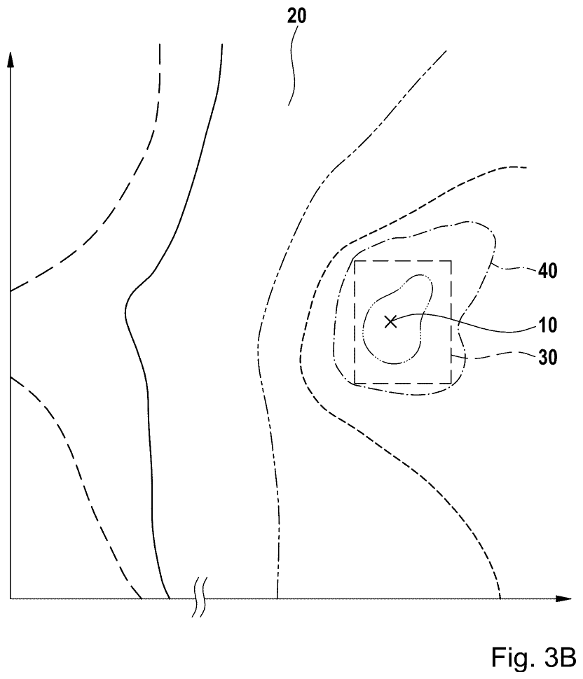

An exemplary result of the determination of the tolerance zone 30 around the target parameter sample 10 is shown in FIG. 3A-3B.

The target parameter sample 10 and the tolerance zone 30 can define a product sample to be produced for the product, hereinafter also referred to as the target product sample.

As schematically illustrated as an option in FIG. 1, for example, the method 100 may further comprise outputting 150 a requirement for the production of the product sample to be produced, on the basis of the target parameter sample 10 and the tolerance zone 30, wherein the requirement is met if (e.g., all) parameters of the product sample to be produced are in the tolerance zone 30. Step 150 in FIG. 2 is referred to as “Conversion of the tolerance zone into individual parameter tolerances” in the exemplary embodiment.

On the basis of the requirement, the production (e.g., prototype construction) can produce the product specimen. The requirement may include an algorithm or be such an algorithm with which it can be checked whether the one or more parameters of the product sample to be produced (i.e., of the product specimen) are in the tolerance zone 30 around the target parameter sample 10. Such an algorithm can be useful, for example, when the tolerance zone is higher-dimensional and deviates strongly from a product space (i.e., from a direct product of intervals).

The determination 140 of the tolerance zone 30 in the ODD can, for example, be carried out in such a way that, in the tolerance zone 30, every distance to the parameterized simulation model assigned to the target parameter sample 10 is less than the maximum tolerable distance. Alternatively, the determination 140 of the tolerance zone 30 in the ODD can, for example, also be carried out in such a way that, in the tolerance zone 30, every distance to the parameterized simulation model assigned to the target parameter sample 10 is less than or equal to the maximum tolerable distance. It is also possible, for example, that the determination 140 of the tolerance zone 30 in the ODD is carried out in such a way that, in the tolerance zone 30, every distance to the parameterized simulation model assigned to the target parameter sample 10 is at most approximately the maximum tolerable distance.

Furthermore, the determination 140 of the tolerance zone 30 in the ODD can be carried out in such a way that the tolerance zone 30 is exactly or approximately maximal. For example, the tolerance zone 30 can be maximized on the basis of the Lebesgue measure. The tolerance zone may, but does not have to, be a zone in the mathematical sense.

Furthermore, the determination 140 of the tolerance zone 30 in the ODD can be carried out in such a way that the tolerance zone 30 is a connected set in the ODD. Alternatively or additionally, it can be carried out in such a way that the tolerance zone 30 is a convex set in the ODD. In particular, the tolerance zone can be a convex, connected set in the ODD.

For example, the tolerance zone 30 may be a manifold, a polytope, in particular a convex polytope, a hyperellipsoid, or a hypercube. A hypercube is particularly advantageous since the parameters and their tolerances are independent of one another.

If this is not the case, the tolerance zone 30 can be defined as an (arbitrary) manifold. In order to reduce the memory requirements of such a manifold, it may be useful to approximate the manifold by a polytope or a hyperellipsoid.

The ODD can be defined by a numerical and/or analytical description. The parameterized simulation model assigned to the target parameter sample 10 can be defined by evaluating the parameterizable analytical simulation model at the target parameter sample 10 in the ODD. As schematically illustrated as an option in FIG. 1, for example, the method 100 may further comprise forming 120 the parameterized simulation model assigned to the target parameter sample 10, wherein the parameterizable analytical simulation model is evaluated at the target parameter sample 10 in the ODD.

Each parameterized simulation model can be defined by evaluating the parameterizable analytical simulation model on a parameter sample in the ODD for the product. As schematically illustrated as an option in FIG. 1, for example, the method 100 may further comprise forming 121 each parameterized simulation model, wherein the parameterizable analytical simulation model is evaluated at an (arbitrary) parameter sample in the ODD.

The method 100 or step 140 may further comprise converting the parameterizable analytical simulation model in order to obtain an associated parameterized simulation model for any ODD sample (e.g., the target parameter sample 10, or a parameter sample of the particular parameterized simulation model). Such a step is referred to as “Conversion of the PAM into PUM at each ODD point” in the exemplary embodiment in FIG. 2, wherein PAM denotes the parameterizable analytical simulation model, PUM denotes a parameterized simulation model of the parameterizable analytical simulation model, and ODD point denotes an (arbitrary, corresponding) parameter sample in the ODD.

The method 100 or step 140 may further comprise establishing a dissimilarity metric function for any pairs consisting of the parameterized simulation model assigned to the target parameter sample 10 and a particular parameterized simulation model in the entire ODD (or a part thereof). Such a function can be a composition of the dissimilarity metric on two converted parameterizable analytical simulation models. Such a step is referred to as “Listing of the metric functions between all PUMs and sample PUMs” in the exemplary embodiment in FIG. 2, wherein the metric functions each denote the dissimilarity metric function.

The actual determination 140 of the tolerance zone in the ODD around the target parameter sample 10 on the basis of the maximum tolerable distance and the dissimilarity metric is referred to as “Calculation of the tolerance zone” in the exemplary embodiment in FIG. 2.

The target parameter sample 10 may be one of a plurality of target parameter samples representative of the ODD. In this case, the parameter samples 20 of each parameterized simulation model can be in a representativeness range of the target parameter sample 10, i.e., be limited to part of the ODD.

As schematically illustrated as an option in FIG. 1, for example, the method 100 may further comprise identifying 160 one or more parameters in the tolerance zone 30 that have a greater influence on the product. This can be carried out, for example, by means of a sensitivity analysis. This can improve understanding of the product and its behavior. In particular in the case of higher-dimensional ODDs, this can be useful since the tolerance zone 30 can then no longer be directly inspected. This can improve understanding of the system in the tolerance zone. The results can be taken into account in the realization of the target product sample.

The method 100 may comprise determining 140 a respective tolerance zone in the ODD around a plurality of target parameter samples 10. Around each target parameter sample, an associated tolerance zone in the ODD can thus be determined in this case.

The method 100 may comprise determining the maximum tolerable distance. The step is referred to as “Determination of the maximum tolerable distance” in the exemplary embodiment in FIG. 2. In the case of a plurality of target parameter samples, this determination can be made globally, i.e., for all target parameters, or can be determined individually for the target parameter samples of the plurality of target parameter samples.

As discussed above, the tolerance zone 30 can be used to ascertain one or more product specimens of which the parameters are in the tolerance zone around the target parameter sample. As an alternative or in addition to the above-discussed possibility of outputting 150 a requirement, the method 100 may comprise comparing stored parameter samples of real product specimens in a database with the tolerance zone, in particular on the basis of a similarity relation. In case of unsatisfactory similarity, one or more instructions can be output on how to produce a sufficiently satisfactory product sample from a real product sample (e.g., through fitting, shimming, etc.). This may, but does not have to, be a representative product sample.

The product specimen that realizes the product sample to be produced can be used to design a product control. The design of the product control can be based in particular on a plurality of product specimens that each realize product samples to be produced. In particular, if the product samples to be produced are representative of the ODD, the draft and/or design of a robust product control can be improved. In particular, as a result, the product control can be designed to be particularly robust and reliable. This can in particular increase the safety of the product.

Furthermore, one or more product requirements can be tested on the basis of the product specimen that realizes the product sample to be produced. The testing of one or more product requirements can be based in particular on the plurality of product specimens that each realize product samples to be produced. As a result, the product can be designed to be robust and reliable. This, too, can in particular increase the safety of the product.

FIG. 2 shows an exemplary embodiment of the method 100. For example, the following steps can be carried out in sequence:
“Conversion of the PAM into PUM at each ODD point”
“Listing of the metric functions between all PUMs and sample PUMs”
“Determination of the maximum tolerable distance”
“Calculation of the tolerance zone,” 140
“Conversion of the tolerance zone into individual parameter tolerances,” 150

FIG. 3A illustrates the exemplary ODD of FIG. 3B with an exemplary and arbitrary plurality of parameterized simulation models (more precisely: their parameter samples 20, shown as points). This plurality of parameterized simulation models is shown for illustration purposes only.

FIG. 3B illustrates an exemplary ODD with a target parameter sample 10 (shown as a cross) surrounded by a tolerance zone 30.

In this example, the ODD is a two-dimensional product space, i.e., it is spanned by two parameters (one parameter in the x direction, another parameter in the y direction), each of which can assume values in an interval. In general, the ODD does not have to be a product space, but can be an (arbitrary) manifold. The dimension of the ODD can be arbitrary. Here, the tolerance zone 30 is a rectangle by way of example.

For this example, the distance (according to the dissimilarity metric) of each parameter sample 20 in the ODD (i.e., more precisely, its parameterized simulation model, some of them shown as points in FIG. 3A) to the parameterized simulation model assigned to the target parameter sample 10 could be shown in 3D i.e., in the z direction orthogonal to the sheet plane. Instead, in 2D, four isolines (e.g., 40) are shown in the z direction with respect to this variable. The four solid lines each form an isoline, i.e., they have the same z-value. In addition to the isolines, a boundary of areas of influence (dashed lines) of the corresponding representative parameterized simulation models is shown.

In FIG. 3A-3B, for example to the left of the boundary of areas of influence (dashed lines), there could be another target parameter sample around which a tolerance zone can also be determined according to the method 100.

Furthermore, a computer system is disclosed, which is designed to execute the computer-implemented method 100 for ascertaining a tolerance zone 30 in an operational design domain (ODD) around a target parameter sample 10 of a parameterizable simulation model for a product. The computer system can comprise a processor and/or a working memory.

Furthermore, a computer program is disclosed, which is designed to execute the computer-implemented method 100 for ascertaining a tolerance zone 30 in an operational design domain (ODD) around a target parameter sample 10 of a parameterizable simulation model for a product. The computer program can be present, for example, in interpretable or in compiled form. For execution, it can be loaded (even in parts) into the RAM of a computer (e.g., of the computer system), for example as a bit sequence or byte sequence. Also disclosed is a computer-readable medium or signal that stores and/or contains the computer program. The medium can comprise, for example, any one of RAM, ROM, EPROM, HDD, SSD, . . . , on/in which the signal is stored.

1-15. (canceled)

16. A computer-implemented method for ascertaining a tolerance zone in an operational design domain (ODD) around a target parameter sample of a parameterizable simulation model for a product, the product being a steer-by-wire steering system and/or a steering system for highly automated driving, the method comprising:
determining the tolerance zone in the ODD around the target parameter sample based on a maximum tolerable distance and a dissimilarity metric, wherein the dissimilarity metric defines a distance between a parameterized simulation model assigned to the target parameter sample and a parameterized simulation model.

17. The method according to claim 16, wherein the target parameter sample and the tolerance zone define a product sample to be produced for the product.

18. The method according to claim 17, further comprising:
outputting a requirement for production of the product sample to be produced based on the target parameter sample and the tolerance zone, wherein the requirement is met when parameters of the product sample to be produced are in the tolerance zone.

19. The method according to claim 18, wherein the requirement includes an algorithm with which it can be checked whether the parameters of the product sample to be produced are in the tolerance zone

20. The method according to claim 16, wherein the dissimilarity metric is based on a gap metric, and/or on a v-gap metric, and/or on an L2 metric.

21. The method according to claim 16, wherein the determining of the tolerance zone in the ODD is carried out in such a way that, in the tolerance zone, every distance to the parameterized simulation model assigned to the target parameter sample is less than the maximum tolerable distance.

22. The method according to claim 21, wherein the determining of the tolerance zone in the ODD is carried out in such a way that the tolerance zone is maximal.

23. The method according to claim 22, wherein the tolerance zone is maximized based on a Lebesgue measure.

24. The method according to claim 16, wherein the tolerance zone is a convex polytope or a hyperellipsoid or a hypercube.

25. The method according to claim 16, wherein the parameterized simulation model assigned to the target parameter sample is defined by evaluating the parameterizable analytical simulation model at the target parameter sample in the ODD.

26. The method according to claim 25, wherein each parameterized simulation model is defined by evaluating the parameterizable analytical simulation model at a parameter sample in the ODD for the product.

27. The method according to claim 16, wherein the target parameter sample is one of a plurality of target parameter samples representative of the ODD.

28. The method according to claim 27, wherein parameter samples of each parameterized simulation model are in a representativeness range of the target parameter sample.

29. The method according to claim 16, further comprising:
identifying one or more parameters in the tolerance zone that have a greater influence on the product.

30. A computer system configured to execute a computer-implemented method for ascertaining a tolerance zone in an operational design domain (ODD) around a target parameter sample of a parameterizable simulation model for a product, the method comprising:
determining the tolerance zone in the ODD around the target parameter sample based on a maximum tolerable distance and a dissimilarity metric, wherein the dissimilarity metric defines a distance between a parameterized simulation model assigned to the target parameter sample and a parameterized simulation model.

31. A non-transitory computer-readable medium on which is stored a computer program for ascertaining a tolerance zone in an operational design domain (ODD) around a target parameter sample of a parameterizable simulation model for a product, the computer program, when executed by a computer, causing the computer to perform the following:
determining the tolerance zone in the ODD around the target parameter sample based on a maximum tolerable distance and a dissimilarity metric, wherein the dissimilarity metric defines a distance between a parameterized simulation model assigned to the target parameter sample and a parameterized simulation model.
